(19) United States
(12) Patent Application Publication
(10) Pub. No.: US 2008/0048172 A1
(43) Pub. Date: Feb. 28, 2008

(54) Gallium Nitride-Based Compound Semiconductor Light-Emitting Device

(75) Inventors: Noritaka Muraki, Chiba (JP); Munetaka Watanabe, Chiba (JP); Hisayuki Miki, Chiba (JP); Yasushi Ohno, Chiba (JP)

Correspondence Address: SUGHRUE MION, PLLC, 2100 PENNSYLVANIA AVENUE, N.W., SUITE 800, WASHINGTON, DC, 20037, US

(73) Assignee: SHOWA DENKO K.K., Minato-ku, Tokyo (JP)

(21) Appl. No.: 10/586,909

(22) PCT Filed: Jan. 28, 2005
(86) PCT No.: PCT/JP05/01645

§ 371 Date: Jan. 8, 2007

Related U.S. Application Data
(60) Provisional application No. 60/542,473, filed on Feb. 9, 2004.

(30) Foreign Application Priority Data
Jan. 30, 2004 (JP) 2004-022668

(51) Int. Cl. H01L 33/00

(52) U.S. Cl. 257/13; 257/E33.005

(57) ABSTRACT

A gallium nitride compound semiconductor light-emitting device includes a crystalline substrate (10), a light-emiting layer (15) of a quantum well structure which is formed of a gallium nitride compound semiconductor barrier layer and a gallium nitride compound semiconductor well layer, which light-emitting layer is provided on a second side of the crystalline substrate, a contact layer (17) formed of a Group III-V compound semiconductor for providing an Ohmic electrode for supplying device operation current to the light-emitting layer, and an Ohmic electrode (18) which is provided on the contact layer and has an aperture through which a portion of the contact layer is exposed. The Ohmic electrode exhibits light permeability with respect to light emitted from the light-emitting layer. The well layer contains a thick portion having a large thickness and a thin portion having a small thickness.

### CROSS REFERENCE TO RELATED APPLICATIONS

This application is an application filed under 35 U.S.C. §111(a) claiming the benefit pursuant to 35 U.S.C. §119(e) (1f the filing date of Provisional Application No. 60/542,473 filed Feb. 9, 2004 pursuant to 35 U.S.C. §111(b).

### TECHNICAL FIELD

The present invention relates to a gallium nitride (GaN) compound semiconductor light-emitting device including a light-emitting layer having a superlattice structure (e.g., a quantum well structure), a contact layer for forming an Ohmic electrode, and a metallic reflecting mirror for reflecting to the outside the light emitted from the light-emitting layer.

### BACKGROUND ART

In recent years, gallium nitride (GaN) compound semiconductors have become of interest as semiconductor material for producing a light-emitting device that emits light of short wavelength corresponding to blue to green light (see, for example, JP-B SHO 55-3834). At present, a GaN compound semiconductor is grown on a substrate (of sapphire (α-Al₂O₃ single crystal), a single crystal of any of a variety of oxides or a Group III-V compound semiconductor single crystal) through metal-organic chemical vapor deposition (MOCVD), molecular-beam epitaxy (MBE) or a similar technique. For example, a GaN compound semiconductor light-emitting layer is formed through such a vapor growth means and has a quantum well (QW) structure including a barrier layer and a well layer. More specifically, the light-emitting layer has a single quantum well (SQW) or multiple quantum well (MQW) structure including gallium indium nitride (compositional formula: Ga_{y}In_{z}N (0≦Y, Z≦1, Y+Z=1)) well layers and GaN barrier layers.

In order to fabricate a light-emitting device, such as an LED or a laser diode (LD), a light-emitting layer must be equipped with a positive (+) Ohmic electrode and a negative (−) Ohmic electrode for providing current for operating the device (device operation current). When an electrically insulating substrate (e.g., sapphire) is employed for producing a GaN compound semiconductor light-emitting device, such as a light-emitting diode (LED), an Ohmic electrode cannot be provided on the backside of the substrate, in contrast to the case where a conductive semiconductor substrate (e.g., silicon carbide (SiC), gallium arsenide (GaAs) or gallium phosphide (GaP)) is employed. Therefore, a positive Ohmic electrode and a negative Ohmic electrode are formed on one surface (front side) of the substrate.

The GaN compound semiconductor for fabricating a GaN compound semiconductor light-emitting device per se is a wide bandgap material, and an Ohmic electrode exhibiting low contact resistance is difficult to provide reliably. Therefore, an n-type or a p-type Ohmic electrode is generally provided by the mediation of a low-contact-resistance layer, which is generally called a “contact layer.” Particularly when a p-type Ohmic electrode is provided on a p-type GaN compound semiconductor layer, which is present on the side where the light emitted from a light-emitting layer is extracted to the outside, the Ohmic electrode is formed from a very thin metallic film and formed on virtually the entire surface of the p-type GaN compound semiconductor layer (see, for example, JP-A HEI 6-314822).

For example, JP-A HEI 6-314822 shown above discloses a technique for fabricating a light-permeable Ohmic electrode from a metallic material, such as gold (Au), nickel (Ni), platinum (Pt), indium (In), chromium (Cr) or titanium (Ti), which is formed into a thin film having a thickness of 0.001 μm to 1 μm. Such an Ohmic electrode as provided on the side where the emitted light is extracted to the outside is formed from a light-permeable material, since absorption of the light emitted from a light-emitting layer is mitigated, thereby effectively extracting the emitted light to the outside.

In addition to formation of the Ohmic electrode from the aforementioned light-permeable electrode material, other techniques for enhancing the efficiency of extracting emitted light to the outside are known (see, for example, JP-A HEI 9-36427). In one disclosed technique, a substrate is formed from a crystalline material that is optically transparent with respect to the wavelength of the emitted light, and a reflecting mirror is provided on the backside of the substrate, which is opposite the side on which a light-emitting device stacked structure is provided. The reflecting mirror reflects the emitted light to the outside vision field and is typically formed from a metallic film.

However, even though the light-emitting layer is formed of a single or multiple quantum well structure, the light-emitting layer that provides high-intensity emission cannot always be produced. Studies conducted by the inventors in an attempt to attain high-intensity emission reveal that the emission intensity is related to (1) the thickness of a well layer having the quantum well structure and (2) presence of dopant (doping impurity element) contained in a barrier layer.

Meanwhile, one known technique for effectively extracting, to the outside, light emitted from the light-emitting layer outside includes forming a light-permeable electrode of a net-shape plane or comb-like plane (see, for example, JP-A 2003-133589). However, in such a case where a light-permeable electrode is provided with apertures which do not absorb emitted light, provision of the apertures disadvantageously reduces the area of the Ohmic electrode, raising a problem of increased device operation voltage (forward voltage) being required. Even though a light-permeable electrode having an aperture is employed, the formed Ohmic electrode is required to attain a forward current of a practical level (e.g., about 3 V), and there is demand for a technique for forming such an electrode.

The present invention overcomes the aforementioned technical drawbacks and provides a GaN compound semiconductor light-emitting device including a light-emitting layer of a quantum well structure for attaining high-intensity emission. The invention also provides a GaN compound semiconductor light-emitting device including a contact layer which has such an appropriate carrier concentration and thickness as to prevent, for example, undesirable increase in forward voltage, particularly in the case where a light-permeable electrode having an aperture is provided.

### DISCLOSURE OF THE INVENTION

The present invention provides a gallium nitride compound semiconductor light-emitting device comprising a crystalline substrate; a light-emitting layer of a quantum well structure which is formed of a gallium nitride compound semiconductor barrier layer and a gallium nitride compound semiconductor well layer, which light-emitting layer is provided on a second side of the crystalline substrate; a contact layer formed of a Group III-V compound semiconductor for providing an Ohmic electrode for supplying device operation current to the light-emitting layer; and an Ohmic electrode which is provided on the contact layer and has an aperture through which a portion of the contact layer is exposed, wherein the Ohmic electrode exhibits light permeability with respect to light emitted from the light-emitting layer, and the well layer contains a thick portion having a large thickness and a thin portion having a small thickness.

In the first mentioned gallium nitride compound semiconductor light-emitting device, the well layer contains a portion having a thickness of 1.5 nm to 0 nm.

In the first or second mentioned gallium nitride compound semiconductor light-emitting device, either the barrier layer or the well layer is doped with an impurity element.

In the third mentioned gallium nitride compound semiconductor light-emitting device, only the barrier layer is doped with an impurity element.

In the fourth mentioned gallium nitride compound semiconductor light-emitting device, the predetermined impurity element added only to the barrier layer is silicon.

In any one of the first to fifth mentioned gallium nitride compound semiconductor light-emitting devices, the contact layer is doped with an n-type impurity element and has a carrier concentration of 5×10¹⁸ cm⁻³ to 2×10¹⁹ cm⁻³.

In any one of the first to sixth mentioned gallium nitride compound semiconductor light-emitting devices, the contact layer is doped with a p-type impurity element and has a carrier concentration of 1×10¹⁷ cm⁻³ to 1×10¹⁹ cm³.

In the seventh mentioned gallium nitride compound semiconductor light-emitting device, the contact layer is doped with a p-type impurity element and has a carrier concentration of 1×10¹⁷ cm⁻³ to 5×10¹⁸ cm⁻³ .

In any one of the first to eighth mentioned gallium nitride compound semiconductor light-emitting devices, the contact layer has a thickness of 1 μm to 3 μm.

In any one of the first to ninth mentioned gallium nitride compound semiconductor light-emitting devices, the Ohmic electrode exhibits a transmittance at the wavelength of emitted light of 30% or higher.

In any one of the first to tenth mentioned gallium nitride compound semiconductor light-emitting devices, the Ohmic electrode has a thickness of 1 nm to 100 nm.

Any one of the first to eleventh mentioned gallium nitride compound semiconductor light-emitting devices further comprises a metallic reflecting mirror for reflecting light emitted from the light-emitting layer to the outside, which mirror is provided on a first side of the crystalline substrate, wherein the metallic reflecting mirror contains a metallic material identical to that contained in the Ohmic electrode.

In the twelfth mentioned gallium nitride compound semiconductor light-emitting device, the metallic reflecting mirror has a multilayer structure including a metallic film which contains a metallic material identical to that contained in the Ohmic electrode.

In any one of the first to thirteenth mentioned gallium nitride compound semiconductor light-emitting devices, the metallic reflecting mirror contains a single-metal film or an alloy film formed from at least one member selected from the group consisting of silver, platinum, rhodium and aluminum.

In any one of the first to fourteenth mentioned gallium nitride compound semiconductor light-emitting devices, the metallic reflecting mirror is in the form of multilayer film.

The present invention also provides a light-emitting diode employing any one of the first to fifteenth mentioned gallium nitride compound semiconductor light-emitting devices.

The present invention further provides a lamp employing the light-emitting diode just mentioned above or any one of the first to fifteenth mentioned gallium nitride compound semiconductor light-emitting devices

The present invention enables to provide a light-emitting device which can operate at low operation voltage, despite having a light-permeable electrode having an aperture for attaining high emission output.

### BRIEF DESCRIPTION OF THE DRAWINGS

FIG. 1 is a plan view showing an electrode configuration employed in Examples 1, 2 and 3.

FIG. 2 is a cross-sectional view showing one example of a stacked structure of the light-emitting device according to the present invention.

FIG. 3 is a plan view of the electrode configuration employed in Example 4.

FIG. 4 is a plan view of the electrode configuration employed in Example 5.

FIG. 5 is a cross-sectional view showing another example of a stacked structure of the light-emitting device according to the present invention.

### BEST MODES FOR CARRYING OUT THE INVENTION

The light-emitting layer of the present invention having a quantum well structure may be formed on sapphire or a hexagonal single crystal (e.g., hexagonal SiC (4H or 6H), wurtzite GaN or zinc oxide (ZnO)), serving as a substrate. In addition, a zinc-blende semiconductor single crystal of GaP, GaAs, Si, etc. may also be employed as a substrate. A gallium nitride compound semiconductor layer serving as a light-emitting layer is generally formed on a substrate which does not lattice-match with the compound semiconductor, other than a hexagonal or cubic GaN substrate. In order to mitigate lattice mismatch with the substrate, a low-temperature buffer layer may be provided between the substrate and a light-emitting layer having a quantum well structure. Alternatively, a GaN compound semiconductor layer serving as a light-emitting layer may be formed, without requiring a low-temperature buffer layer, through a lattice-mismatch crystal epitaxial growth technique based on the seeding process (SP). The SP method is particularly advantageous, since a single-crystal film (e.g., aluminum nitride (AlN)) exhibiting a large lattice-mismatch degree can be grown directly on a substrate (e.g., sapphire) at such a high temperature that enables formation of a GaN compound semiconductor layer. The SP method can simplify steps of growing a light-emitting layer or other layers, thereby enhancing productivity of GaN compound semiconductor light-emitting devices.

The light-emitting layer of the present invention is preferably provided by the mediation of, for example, an undercoat layer formed of an n-type or p-type GaN compound semiconductor. For example, the light-emitting layer is provided on an n-type GaN undercoat layer which has been grown on a low-temperature buffer layer at about 600° C. or lower. Alternatively, the light-emitting layer is provided on an n-type GaN layer which has been grown directly on a substrate (e.g., sapphire) through the aforementioned SP method. In the case where the SP method is employed for growth, the n-type GaN layer preferably remains undoped or has a low carrier concentration of 1×10¹⁷ cm⁻³ to 1×10¹⁸ cm⁻³. The undercoat layer preferably has a thickness of 1 μm or more, more preferably 5 μm or more.

The GaN compound semiconductor undercoat layer which exhibits a bandgap not less than that of a barrier layer included in a light-emitting layer having a quantum well structure may also serve as a lower cladding layer. The undercoat layer also serving as a cladding layer may be formed of aluminum gallium nitride (compositional formula: AlₓGa_{y}N (0≦X, Y≦1, X+Y=1)), GaN, Ga_{y}In_{z}N (0≦Y, Z≦1, Y+Z=1) or a similar material. The lower cladding layer may include a periodically multilayered structure, in which GaN compound semiconductor layers having different specific lattice constants and different specific compositional proportions are alternately stacked. For example, a hetero-multilayered structure, in which AlₓGa_{y}N (0≦X, Y≦1, X+Y=1) and Ga_{y}In_{z}N (0≦Y, Z≦1, Y+Z=1) are alternately stacked, can prevent propagation of misfit dislocations to an upper portion, thereby providing a light-emitting layer of high crystallinity. The entirety of the lower cladding layer may be formed from the multilayered structure so as to attain the above effect. The multi-layered structure may also be formed by alternately stacking GaN compound semiconductor layers having different specific amounts of impurities for doping or different thicknesses.

To the lower cladding layer, a contact layer for forming an Ohmic electrode may be joined. The conduction type of the GaN compound semiconductor lower cladding layer is the same as that of the GaN compound semiconductor contact layer. For example, an n-type contact layer is provided on an n-type undercoat layer. In this case, when the contact layer is formed from a GaN compound semiconductor layer exhibiting a bandgap not less than that of a barrier layer included in a light-emitting layer having a quantum well structure, the formed contact layer also serves as the lower cladding layer. On an n-type lower cladding layer, an n-type contact layer is provided. The carrier concentration of the contact layer may be equivalent to that of the lower cladding layer, but is preferably greater than that of the lower cladding layer so as to form an Ohmic contact electrode exhibiting low contact resistance. The n-type contact layer is preferably formed from an n-type gallium nitride compound semiconductor having a carrier concentration of 5×10¹⁸ cm⁻³ to 2×10¹⁹ cm⁻³. Through controlling the carrier concentration to fall within the above range, a GaN compound semiconductor light-emitting device exhibiting forward voltage as low as 2.9 V to 3.3 V (at a forward current of 20 mA) can be produced consistently, despite employment of a light-permeable electrode having an aperture.

The contact layer may be provided under the lower cladding layer. However, the contact layer closer in position to a crystalline substrate that lattice-mismatches with the contact layer becomes a layer of increased crystal defect density (e.g., misfit dislocation density) due to lattice mismatch with the crystalline substrate. When an Ohmic electrode is provided on such a crystalline layer having many crystal defects, an Ohmic electrode exhibiting excellent electrical properties may fail to be produced. For example, an electrode exhibiting local breakdown attributable to dislocations is resulted, which is not preferred. When the contact layer is formed from a GaN compound semiconductor containing a non-nitride Group V element (e.g., compositional formula: AlₓGa_{y}In_{z}N₁₋ₐMₐ (0≦X, Y, Z≦A1, X+Y+Z=1, 0≦a<1, wherein M represents a Group V element other than nitrogen), an Ohmic electrode that contains few local breakdown portions can be advantageously formed. When the thickness of the n-contact layer is increased to 1 μm or more, forward voltage can be lowered. However, when the thickness is increased to 3 μm or more, surface flatness is impaired, thereby failing to bond an Ohmic electrode to the surface.

On the lower cladding layer or the lower contact layer, a light-emitting layer having a quantum well structure is provided. For example, the light-emitting layer has a single or multiple quantum well structure including AlₓGa_{y}N (0≦X, Y≦1, X+Y=1) barrier layers and Ga_{y}In_{z}N (0≦Y, Z≦1, Y+Z=1) well layers. Although the carrier concentration of each barrier layer may differ from that of each well layer, the conduction type of the GaN compound semiconductor barrier layers and that of the GaN compound semiconductor well layers are required to match with each other. According to the present invention, the well layers have virtually a non-uniform thickness as in the case with conventional well layers. That is, the well layer of the invention is formed from a GaN compound semiconductor having a non-uniform thickness, i.e. including a thick portion and a thin portion. Particularly preferably, the well layer is formed from an indium-containing GaN compound semiconductor and contains a portion having a thickness of 1.5 nm or less. The portion having a thickness of 1.5 nm or less is not necessarily distributed uniformly in the entirety of each well layer and may be localized in a portion of each well layer. The well layer is not necessarily a continuous layer, and an area where no well layer is present (i.e., a well layer portion having a thickness of 0 nm) may be included.

Such a partially thinned well layer having a non-uniform thickness can be formed through a specific method for supplying a Group V source into a film formation system during film formation. For example, a partially thinned well layer composed of Ga_{y}In_{z}N (0≦Y, Z≦1, Y+Z=1) is formed by changing the supply rate of a nitride source in a time-dependent manner, rather than by supplying a nitrogen source at a constant rate during film formation. Particularly when the supply rate of nitrogen source is periodically reduced, the thinned well layer can be effectively formed. For example, during growth for forming a well layer, the supply rate of nitrogen source is reduced or increased second by second. Even when the supply rate is reduced, a certain level of supply rate for preventing sublimation of nitrogen from a growing layer is maintained. When growth is continuously performed under nitride-source-poor conditions for a long period of time, many thin portions can be formed in a single well layer. One possible mechanism of thinning of a well layer is as follows. When the nitrogen (component element)-poor conditions persist for a long period, condensation of Group III element vapor is promoted, to form liquid drops, and formation of the drops provides Group III-element-poor conditions surrounding the drops, whereby the thickness of the formed film is reduced. The presence of the thin portion in the well layer can be observed, and the thickness of the thin portion can be determined through observation of a cross-section of the well layer, for example, under a transmission electron microscope (TEM) (through cross-section TEM technique).

Alternatively, a well layer having a non-uniform thickness can also be formed by intentionally reducing the supply rate of Group V element (e.g., nitrogen) source to a film formation system in an initial stage of the well layer growth. For example, when a Ga_{y}In_{z}N (0≦Y, Z≦1, Y+Z=1) well layer is formed through atmospheric-pressure MOCVD or reduced-pressure MOCVD by use of trimethylgallium (molecular formula: (CH₃)₃Ga) and ammonia (molecular formula: NH₃) serving as sources for component elements, a so-called V/III ratio (concentration of Group V element source supplied to a film formation system to concentration of Group III source supplied to a film formation system; i.e., NH₃/(CH₃)₃Ga concentration ratio) is controlled to 1×10³ to 1×10⁴, more preferably 2×10³ to 5×10³. The film formation at such a comparatively low V/III ratio is preferably performed within a period of time from the start of growth to the point of time at which the thickness reaches ⅓ the thickness of interest. If the growth is performed at low V/III ratio until the film has a thickness of interest, a desired layer is not formed, and only liquid drops rich in Group III element are formed on a lower cladding layer, a contact layer or a barrier layer.

When any of the aforementioned growth techniques is employed, the formed light-emitting layer having a quantum well structure including a well layer which contains a thin portion and has a non-uniform thickness can lower forward voltage of the GaN compound semiconductor light-emitting device. For example, even when a conventional light-permeable electrode which has an area in contact with a contact layer or a similar layer reduced through provision of an aperture (e.g., a light-permeable electrode having a percent aperture of 70%) is employed, a GaN compound semiconductor light-emitting device exhibiting a forward voltage as low as 3.3 V or lower at a forward current of 20 mA can be provided. As used herein, the term “percent aperture” refers to a ratio an area of the aperture as projected on the surface area of the layer on which the electrode has been formed to the surface area.

The forward voltage can be further lowered through employment of a light-emitting layer having a quantum well structure fabricated from an intentionally doped (impurity-added) well layer or barrier layer. For example, when a light-emitting layer having a quantum well structure including a well layer doped with an n-type impurity element is employed, a GaN compound semiconductor light-emitting device exhibiting low forward voltage can be produced. An impurity-doped well layer exhibiting low resistance can lower forward voltage. When the quantum well structure forming the light-emitting layer is fabricated from a limited number of well layers, the greater the number of employed well layers exhibiting low resistance by virtue of impurity-doping, the greater the effect of lowering forward voltage. However, addition of a dopant impairs crystallinity of the well layer, and light of an undesired wavelength may be emitted. Thus, when n-type well layers are employed, the well layer closest in position to the p-type cladding layer is preferably undoped (i.e., is an undoped well layer to which no impurity is intentionally added).

As described above, when the light-emitting layer having a quantum well structure includes an impurity-doped well layer, forward voltage can be lowered. However, light of an undesired wavelength may be emitted. An effective technique for producing a GaN compound semiconductor light-emitting device which emits light of a desired wavelength and which exhibits low forward voltage is fabrication of a light-emitting layer having a quantum well structure from an impurity-doped barrier layer. Differing from the case of well layer, in order to produce a light-emitting device which exhibits low forward voltage and prevents variation of emission wavelength, it is most effective to fabricate all the barrier layers for forming the quantum well structure from an impurity-doped GaN compound semiconductor exhibiting low resistance. For example, an n-type barrier layer which is doped with a Group IV element at an average atom density in the layer of 1×10¹⁷ cm⁻³ to 5×10¹⁸ cm⁻³ and which exhibits low resistance is preferably employed.

For example, the light-emitting layer having a quantum well structure is fabricated by alternately stacking an Si-doped n-type GaN barrier layer and an undoped Ga_{y}In_{z}N well layer and repeatedly (5 times) stacking the laminate on an n-type low-resistance GaN contact layer. Through employment of the light-emitting layer, even when a light-permeable electrode which has an aperture having the aforementioned percent aperture is provided, a GaN compound semiconductor light-emitting device exhibiting a forward voltage as low as 3.3 V or lower at a forward current of 20 mA can be provided. If an impurity-doped barrier layer exhibiting low resistance is employed, even when the layer joined to a contact layer or a lower cladding layer is a barrier layer or a well layer, the same effect of lowering forward voltage can be attained.

When the light-emitting layer having a quantum well structure includes an impurity-doped GaN compound semiconductor layer exhibiting low resistance serving as a barrier layer, forward voltage can be lowered. The effect can be attained regardless of the type (well layer or barrier layer) of the stack-start layer and the stack-end layer of the quantum well structure.

The light-emitting layer according to the present invention having a quantum well structure including an impurity-doped GaN compound semiconductor barrier layer exhibiting low resistance may be formed through MOCVD or vapor growth means, such as molecular-beam epitaxy (MBE) or hydride vapor phase epitaxy (VPE). A barrier layer doped with silicon (Si) or germanium (Ge) is formed by use of a doping gas, such as silane (molecular formula: SiH₄), disilane (molecular formula: Si₂H₆) or germane (molecular formula: GeH₄) during vapor phase growth of the layer. A quantum well structure including a GaN barrier layer and a Ga_{y}In_{z}N well layer is preferably formed at 650° C. to 900° C. When the quantum well structure of this type is formed, the barrier layer and the well layer may be formed at virtually the same temperature. When the barrier layer is formed from aluminum (Al)-containing AlₓGa_{y}N instead of GaN, a growth temperature higher than the GaN barrier layer growth temperature is advantageously employed.

The well layer of the present invention included in the quantum well structure preferably has a thickness of 1 nm to 15 nm. The barrier layer preferably has a thickness of 10 nm to 50 nm. The thickness of the barrier layer is not necessarily reduced in accordance with the thickness of the well layer. The quantum well structure appropriately contains 5 to 20 well layers. Since the well layer of the present invention has position-dependent non-uniformity in thickness, increasing the number of well layers provides more protrusions and depressions on the surface of the light-emitting layer having a quantum well structure. Therefore, in the case where a thick well layer is employed, when the number of well layers employed in the quantum well structure is reduced, a flat-surface upper layer (e.g., p-type upper cladding layer) is advantageously formed on the surface of the light-emitting layer.

The so-called cladding layer which is provided on the light-emitting layer of the present invention having a quantum well structure and on the side where the emitted light is extracted to the outside may be formed of AlₓGa_{y}In_{z}N₁₋ₐMₐ (0≦X, Y, Z≦1, X+Y+Z=1, 0≦a<1, wherein M represents a Group V element other than nitrogen). For example, a p-type cladding layer may be formed of AlₓGa_{y}N (0≦X, Y≦1, X+Y=1) which is doped with a Group II element serving as p-type dopant. The p-type cladding layer is preferably formed from a semiconductor material having a bandgap greater than that of a barrier layer included in the quantum well structure so as to prevent overflow of electrons poured into the light-emitting layer and effectively attain radiation recombination for providing light emission in the light-emitting layer. The upper cladding layer which is formed from a semiconductor material having a bandgap greater than that of a barrier layer included in the quantum well structure and which is provided on the side where the emitted light is extracted to the outside is effective for extracting the light emitted from the light-emitting layer to the outside. The upper cladding layer is preferably a low-resistance layer having a high carrier concentration so as to effectively inject carriers which undergo radiation recombination in the light-emitting layer.

Similar to the case of the aforementioned lower cladding layer, an upper cladding layer having a multilayered structure, in which semiconductor thin layers having different specific lattice constants and different compositional proportions are alternately stacked, can prevent propagation of through dislocations from a lower portion to an upper portion. An upper cladding layer having a multilayered structure, in which GaN compound semiconductor layers having different specific dopant concentrations and different thicknesses are alternately stacked, can also prevent propagation of dislocations through the layer. Most preferably, such a multilayered structure is fabricated by stacking thin layers each having a thickness equal to or smaller than the deformation-related critical thickness. For example, the multilayered structure is fabricated from GaN layers having a thickness of 5 nm and Ga_{y}In_{z}N layers having a thickness of 5 nm or less and an indium composition ratio of more than 0 and not greater than 0.2, 0<Y≦0.2, Y+z=1).

The p-type upper cladding layer may be formed from a boron phosphide semiconductor material, which is the Group III-V compound semiconductor material containing boron (B) and phosphorus (P) as component elements. Particularly, boron monophosphide (BP) which has been grown through MOCVD and which exhibits a bandgap of 3.5 eV or higher at room temperature exhibits sufficient permeability with respect to emitted light of short wavelength and is suitable for forming a low-resistance p-type cladding layer. In addition, boron monophosphide readily provides a low-resistance layer in an as-grown state, despite being undoped. In other words, although AlₓGa_{y}In_{z}N requires a cumbersome step of electrically activating a doped p-type impurity element (i.e., converting to an acceptor) through heating after completion of vapor phase growth, boron phosphide readily provides a low-resistance layer of p conduction type in a simple manner.

An Ohmic electrode exhibiting lower contact resistance can be formed on an upper cladding layer by the mediation of a low-resistance contact layer, rather than directly on the upper cladding layer. Thus, the low-resistance layer is suitable for producing a GaN compound semiconductor light-emitting device exhibiting low forward voltage. The contact layer accompanying the upper cladding layer is formed from a GaN or boron phosphide (BP) compound semiconductor layer exhibiting the conduction type opposite that of the contact layer accompanying the lower cladding layer. The conduction type of the contact layer for forming a light-permeable Ohmic electrode having an aperture is the same as that of the upper cladding layer (unless there is intended formation of a current-confining-type LD or a current-blocking layer). The p-type GaN compound semiconductor contact layer for forming a p-type Ohmic electrode suitably has a carrier concentration of 1×10¹⁷ cm⁻³ to 5×10¹⁸ cm⁻³. When a p-type contact layer is formed from boron phosphide, the carrier concentration is preferably 5×10¹⁸ cm⁻³ to 1×10²⁰ cm⁻³. The contact layer formed from any material suitably has a thickness of 0.1 μm to 1 μm.

Onto each contact layer exhibiting a specific conduction type and formed so as to be in contact with an upper or lower cladding layer, an Ohmic electrode exhibiting the corresponding conduction type is formed, thereby forming a light-emitting device. On the n-type contact layer formed of a GaN compound semiconductor material, there may be provided an n-type Ohmic electrode (negative electrode) formed of a widely used metallic material, such as aluminum (Al), titanium (Ti), nickel (Ni), gold (Au), chromium (Cr), tungsten (W) or vanadium (V). A plurality of metallic films formed of the metallic material or alloy material thereof may be stacked such that a metallic stacked film having a total thickness of about 1 μm is formed. The thus formed n-type Ohmic electrode also serves as a pad electrode. When the metallic thin film having a thickness of 1 nm to 100 nm is formed, the film serves as a light-permeable Ohmic electrode that effectively transmits emitted light to the outside.

The p-type Ohmic electrode (positive electrode) provided on the p-type contact layer may be formed from a metallic material, such as platinum (Pt), palladium (Pd), gold (Au), chromium (Cr), nickel (Ni), copper (Cu) or cobalt (Co). The metallic films may be used singly or in combination so as to form the positive electrode. The thickness of the metallic electrode film serving as a light-permeable electrode is advantageously small so as to form a light-permeable electrode exhibiting high emission transmittance. However, when the thickness of the metallic electrode film is reduced, electric resistance against flow of device operation current increases, and such a film tends to be damaged during an electrode formation process, which is disadvantageous. Therefore, a metallic film or an alloy film for forming a light-permeable electrode preferably attains a transmittance with respect to emitted light of 30% to 80%. The light-permeating p-type Ohmic electrode is preferably formed from a metallic film or an alloy film having a thickness of 1 nm to 100 nm. A metal film having such a thickness may be formed through a thin film formation means, such as high-frequency sputtering or vacuum vapor deposition. When the light-permeable electrode is formed from an electrode of a multilayer structure, the total thickness of the multilayer structure is preferably limited to 100 nm or less. A portion of the p-type Ohmic electrode provided on a p-type GaN compound semiconductor layer, which portion is in contact with the surface of the GaN semiconductor layer, is preferably formed of gold (Au) or a gold alloy film, when formation of the electrode has been completed.

Emitted-light permeability of the p-type Ohmic electrode can be enhanced by forming the electrode from a metal oxide film serving as a component. Examples of the metal oxide which can form a p-type Ohmic electrode exhibiting high light permeability include nickel oxide (NiO: stoichiometry not limited to 1:1) and cobalt oxide (CoO: stoichiometry not limited to 1:1). Any of these metal oxide films is preferably stacked on a gold or gold alloy film provided on a GaN or boron phosphide compound semiconductor contact layer so as to be in contact with the contact layer. Such an electrode having a multilayer structure including a metal oxide film may be formed by sequentially stacking an Au layer, and an Ni or Co layer, and oxidizing the formed stacked body in an oxygen-containing atmosphere. Alternatively, a light-permeable electrode including an Au layer that is in contact with the contact layer and an Ni or Co oxide layer provided on the Au layer may be formed through a reverse stacking sequence; i.e., depositing Ni film or Co film, stacking Au film and oxidizing the stacked body. The flexibility of stacking sequence is attributable to the fact that a transition metal, such as Ni or Co, readily undergoes oxidation as compared with gold (Au) and readily diffuses.

The light-permeable electrode per se formed of a metallic film that transmits light emitted from the light-emitting layer may be provided uniformly on virtually the entire surface of the contact layer present on the side where the emitted light is extracted to the outside. However, when the light-permeable electrode is provided with an aperture (opening) which does not absorb but transmits the light emitted from the light-emitting layer, emitted light can be more effectively extracted to the outside. A light-permeable electrode having an aperture is formed by removing a specific portion of the metallic film forming the light-permeable electrode through, for example, a selective patterning means and a selective etching means. For example, through provision of apertures having a shape (circle, ellipse or polygon) as viewed in a top plane of the electrode in a regular pattern, a light-permeable metallic film electrode having a net shape is formed. When apertures having a shape (square, rectangle or rhombus) as viewed in a top plane of the electrode are provided in a regular pattern, a light-permeable metallic film electrode having a lattice shape is formed. The light-permeable electrode may have other plan view shapes. Examples include a comb shape having a belt portion and fine wire portions branching from the belt portion; a pattern in which belt portions extend radially outward from a pad electrode for wire bonding; and a concentric circle pattern.

Whichever plan view shape of the light-permeable electrode is employed, the aperture must be provided such that device operation current can be diffused uniformly over the entire light-emitting layer via a contact layer. Therefore, it is essential that portions other than the aperture are connected with one another to establish electrical conduction. The light-permeable electrode of the present invention per se exhibits excellent light permeability, since the electrode portion other than the aperture of the light-permeable electrode is formed from a metallic thin film that enables transmission of emitted light. In addition to having the above characteristic, the light-permeable electrode more effectively transmits emitted light to the outside by virtue of the apertures provided. The permeability increases through increase in total projection surface area of the apertures, and such increased permeability is advantageous for fabricating a high-emission-intensity GaN semiconductor light-emitting device. However, since the area where an electrode is provided decreases, the area where device operation current can be diffused decreases. Thus, the percent total surface area of apertures is preferably 30% to 80% the contact layer surface so as to sufficiently diffuse device operation current over the layer and maintain high transmittance with respect to emitted light.

In the light-permeable electrode processed so as to have apertures, the minimum horizontal width (lateral width) of the remaining metallic film forming the Ohmic electrode and the horizontal width of the aperture are appropriately controlled, whereby the efficiency of extracting emitted light to the outside can be enhanced. The term “horizontal width of the metallic film” refers to the width of a portion of metallic electrode film sandwiched by adjacent apertures. In other words, the horizontal width refers to the distance between two apertures disposed opposite each other. The horizontal width of the aperture corresponds to the diameter when the aperture has a circular shape and to the longest diagonal line when the aperture has a square or polygonal shape. The minimum horizontal width (lateral width) of the remaining metallic film forming the Ohmic electrode is preferably 10 μm or less, more preferably 3 μto 5 μm. Although the metallic film can be processed into a fine pattern having a horizontal width less than 0.5 μm (e.g., 0.25 μm) through electron-beam lithography, the thus-formed fine wire is not suited for fabricating, for example, an Ohmic electrode of a large-scale LED (one side: ≧0.5 mm) that is operated by large current flow, since the metallic film is excessively heated upon passage of large current flow (e.g., >100 mA), due to an increased electric resistance against current flow, thereby possibly breaking the fine wire portions. The maximum horizontal width of the aperture is 50 μm or less, preferably 20 μm or less, more preferably 8 μm or less. In order to provide apertures at consistent precision, the width is preferably 0.5 μm or more.

To a portion of the light-permeable electrode of the present invention, which per se exhibits light permeability to emitted light, a lead for supplying device operation current may be directly bonded. Generally, conventional bonding methods include removing a portion of a light-permeable electrode so as to expose a contact layer and, if required, other layers, forming a pad electrode for bonding on the exposed semiconductor layer, and bonding a lead to the pad electrode. In contrast, since the light-permeable electrode of the present invention is provided with apertures as described above, lead can be bonded through an aperture without requiring a pad electrode or bonding of the lead to the pad electrode, whereby device operation current can be conveniently supplied directly to the light-permeable electrode. Each aperture is surrounded by the remaining light-permeable metallic film electrode and steps downward from the surface of the electrode. Therefore, wire lead can be inserted in the stepped-down portion and is reliably bonded as held under pressure by the metallic film electrode material.

The aperture at which a lead is secured may be any of the apertures of the light-permeable electrode. Preferably, a lead is bonded to an Ohmic electrode of one conduction type at an aperture that is present as far as possible from an Ohmic electrode of the opposite conduction type. In the case of a GaN compound semiconductor device having a square plan-view shape, with respect to an Ohmic electrode present at one corner of the square, lead is bonded, at any of the apertures of the other Ohmic electrode present at the diagonal of the device square. In another case in which an Ohmic electrode is provided in the vicinity of the midpoint of one side of the square, lead is bonded at an aperture present in an area in the vicinity of the midpoint of the opposite side. In yet another case where an Ohmic electrode is provided in an area in the vicinity of one corner, lead is bonded at an aperture present along a side which does not form the corner. Alternatively, regardless of the position at which an Ohmic electrode is provided, lead may be bonded at an aperture present at a generally center position of the light-permeable electrode. According to the invention, a lead can be advantageously bonded at any aperture in a simple manner, in contrast to the conventional method including intentionally removing a portion of the formed light-permeable electrode so as to form a pad electrode. The exposed contact layer surface is advantageously employed for securing a pad electrode onto the contact layer.

In addition to provision, on the side where emitted light is extracted, of a light-permeable Ohmic electrode formed of the light-permeable metallic thin film of the present invention, a reflecting mirror for reflecting emitted light to the upper face or side face of the device is provided on the backside of the crystalline substrate, whereby a GaN compound semiconductor light-emitting device exhibiting high efficiency of extracting emitted light to the outside can be fabricated. The term “backside” refers to the surface opposite the surface of a substrate on which a multilayer structure for the light-emitting device is provided. When an optically transparent crystalline substrate that transmits the light emitted from the light-emitting layer is employed, efficiency of extracting emitted light to the outside is remarkably enhanced through provision of a reflecting film on the backside. The reflecting film for reflecting emitted light to the outside may be formed from metallic material, such as silver (Ag), platinum (Pt), rhodium (Rh) or aluminum (Al).

Particularly when the reflecting mirror is formed from the same metallic or alloy material film as employed for forming the light-permeable Ohmic electrode, a GaN compound semiconductor light-emitting device exhibiting high efficiency of extracting emitted light to the outside can be fabricated through a simple procedure. A metal (e.g., palladium (Pd), rhodium (Rh) or platinum (Pt)) film is preferably employed as a material for forming a light-permeable electrode and a reflecting mirror. A reflecting mirror of a multilayer structure formed from such metal films advantageously serves as a reflecting mirror that reflects emitted light to the outside. In a preferred mode for fabricating a reflecting mirror of a multilayer structure exhibiting high reflection efficiency, the multilayer structure is obtained from the same metal films as employed for forming the light-permeable electrode, and the reflecting mirror is directly deposited on the backside of the crystalline substrate (i.e., the reflecting mirror is disposed so as to opposing to the light-permeable electrode). Through employment of the multilayer structure, emitted light is reflected at a plurality of layers, leading to enhancement of the efficiency of reflecting emitted light to the outside. Each of the metal films forming the reflecting mirror of a multilayer structure is varied in accordance with the wavelength of the light emitted from the light-emitting layer. In order to reflect emitted light of a longer wavelength, the reflecting mirror of a multilayer structure is fabricated from thicker metal films. A preferred thickness of metal film for forming the reflecting mirror of a multilayer structure is obtained by dividing wavelength (λ) of emitted light by 4 (i.e., λ/4).

The light-emitting layer of a quantum well structure including a well layer of the present invention which has a non-uniform thickness, i.e. contains a thick portion having a large thickness and a thin portion having a small thickness, enables to provide high-intensity light emission.

The light-emitting layer of a quantum well structure including a barrier layer doped with an impurity element enables to lower forward voltage.

The aperture of the light-permeable electrode provided on the side where the light emitted from a light-emitting layer of a quantum well structure is extracted to the outside does not absorb the light emitted from the light-emitting layer and allows extraction of the light to the outside. The aperture is preferably stepped down, since a lead inserted into the aperture is reliably bonded as tightly held by a remaining Ohmic metallic film portion surrounding the aperture.

The metallic reflecting mirror which is provided on the backside of the crystalline substrate and which is formed from the same metallic material film as employed for forming the light-permeable Ohmic electrode enables to effectively reflect the emitted light to the outside.

### EXAMPLE 1

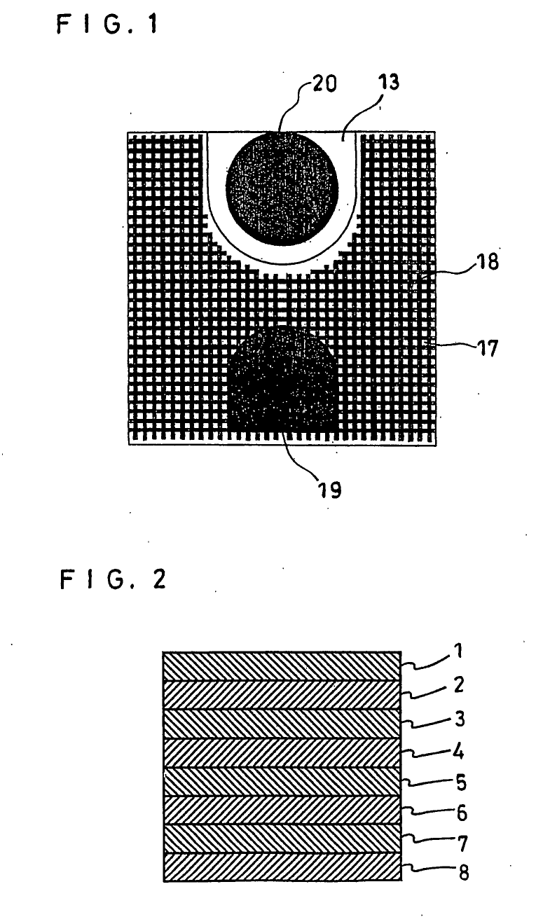

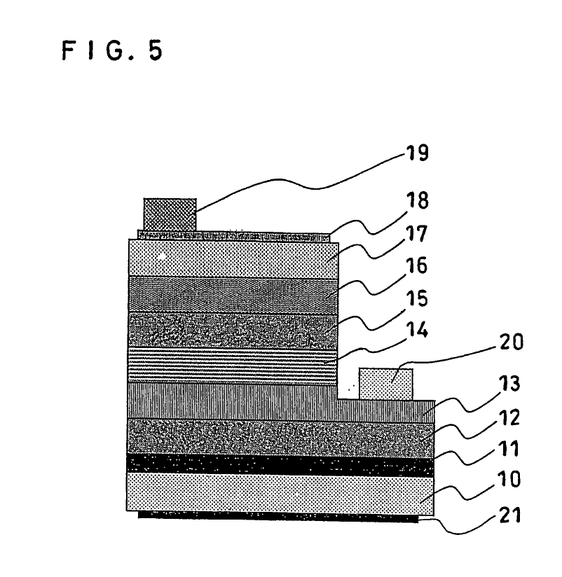

FIG. 2 and FIG. 5 are cross-sectional views of exemplary semiconductor light-emitting devices according to the present invention. As shown in FIG. 2 (FIG. 5), the light-emitting device includes a sapphire substrate 8 (10) and a stacked semiconductor substrate in which an AlN buffer layer 7 (11), an undoped GaN layer 6 (12), an n-type GaN contact layer 5 (13), an n-type InGaN cladding layer 4 (14), an active layer 3 (15) of a multiple quantum well structure including InGaN well layers and Si-doped GaN barrier layers, a p-type AlGaN cladding layer 2 (16) and a p-type GaN contact layer 1 (17) are successively stacked. On the p-type GaN contact layer 1 (17), a first layer formed of Au and a second layer formed of Ni oxide are stacked, and the stacked layers are formed so as to form an ohmic electrode (18) of a lattice-shape pattern. FIG. 1 is a plan view of the semiconductor light-emitting device shown in FIG. 5. P In the semiconductor structure, the n-type GaN contact layer 13 had a carrier concentration of 1×10¹⁹ cm⁻³ and a thickness of 2 μm. Each GaN barrier layer included in the active layer 15 was doped with Si at a concentration of about 1×10¹⁸ cm⁻³. The p-type GaN contact layer 17 had a carrier concentration of 8×10¹⁷ cm⁻³.

The light-permeable electrode 18 was formed so as to assume a lattice-like pattern shown in FIG. 1. The width of an aperture was 7.5 μm, and the width of a fine wire portion was 3 μm. The percent total area of the apertures with respect to the entire area of the corresponding surface is approximately 50%.

The light-permeable electrode of the semiconductor light-emitting device shown in FIG. 1 was fabricated through the following procedure. Firstly, through a conventional photolithographic technique and a conventional lift-off technique, a first layer formed of Au and a second layer formed of Ni oxide were provided exclusively on an area of the p-type GaN layer where a light-permeable electrode was to be formed. Upon formation of the first and second layers, a semiconductor substrate was placed in a vacuum deposition apparatus, and Au was vapor-deposited on the p-type GaN layer (thickness: 7.5 nm) at 3×10⁻⁶ Torr, followed by vapor deposition of Ni (thickness: 5 nm) in the same vapor chamber. The Au- and Ni-deposited substrate was removed from the vacuum chamber and subjected to so-called lift-off process, thereby forming a patterned thin film shown in FIG. 2. Thus, a thin film consisting of the first layer formed of Au and the second layer formed of Ni oxide was provided on the p-type GaN layer. The thin film was found to assume dark gray with metallic gloss and exhibit virtually no light permeability. The substrate was heated in an annealing furnace at 450° C. for 10 minutes in an atmosphere (nitrogen flow containing 5% oxygen). After annealing, the light-permeable electrode of the removed substrate was found to assume bluish dark gray and exhibit light permeability. Notably, the heat treating was performed in order also to establish Ohmic contact between the electrode and the semiconductor.

Subsequently, through a conventional photolithography technique, a p-type electrode bonding pad 19 having a Ti/Al/Ti/Au (from the semiconductor surface) layered structure was formed. The area where the bonding pad was formed was provided by use of a pattern having a cut-away portion.

The light-permeable electrode fabricated through the above method was found to exhibit a transmittance with respect to light (470 nm) of 60%. The transmittance was determined by use of a sample for transmittance determination obtained by processing the same light-permeable electrode so as to have appropriate dimensions.

Subsequently, a portion of the n-type layer where an n-type electrode was to be provided was exposed through dry etching. In addition to the above-described formation of the p-type electrode, an n-type electrode 20 having a structure of Ti/Au (from the semiconductor layer) was formed on the exposed portion.

The backside of a wafer on which the electrodes were formed in the above manner was ground and polished, thereby adjusting the thickness of the wafer to 80 μm. A stacked layer portion of the thinned wafer was marked off by use of a laser scriber, followed by breaking, thereby yielding device chips (350 μm×350 μm). Each of the chips was placed on a lead frame and wire-bonded, thereby fabricating a light-emitting diode. The diode exhibited an emission output of 5 mW and a forward voltage of 2.9 V at a current of 20 mA. The light-permeable electrode was observed under a microscope, while the diode was emitting light through passage of electricity. As a result, each chip achieved uniform light emission through the light-permeable electrode.

### COMPARATIVE EXAMPLE 1

The same stacked structure as employed in Example 1 was used, except that an n-type contact layer having a carrier concentration of 1×10¹⁸ cm⁻³, Si-undoped barrier layers included in the active layer and a p-type contact layer having a carrier concentration of 8×10¹⁶ cm⁻³ were employed. Through a technique identical to that employed in Example 1, a light-permeable electrode of the same pattern was formed on the semiconductor stacked substrate. The fabricated element exhibited an emission output of 5 mW and a forward voltage of 4.0 V at a current of 20 mA.

### EXAMPLE 2

In Example 2, an Al reflecting film 21 was provided on the backside of the same chip as produced in Example 1. The reflecting film was formed by placing each cut chip on a tacky vinyl polymer sheet such that the backside of the chip faces upward, putting the sheet in a vapor deposition apparatus and vapor-depositing Al. The fabricated element exhibited a device operation voltage of 2.9 V at a current of 20 mA which is almost equivalent to that obtained in Example 1. The emission output was elevated to 10 mW.

### EXAMPLE 3

In Example 3, the procedure of Example 1 repeated, except that Ni was changed to Co to thereby fabricate an electrode formed of Au/CoO on a wafer having the same stacked structure as employed in Example 1. The fabricated element exhibited a device operation voltage of 2.95 V at a current of 20 mA which is almost equivalent to that obtained in Example 1. The emission output was found to be 5 mW. The lattice-shaped light-permeable electrode employed in Example 3 was formed by use of a mask having no cut-out portion for providing a bonding pad. However, wire-bonding was performed without any problems.

### EXAMPLE 4

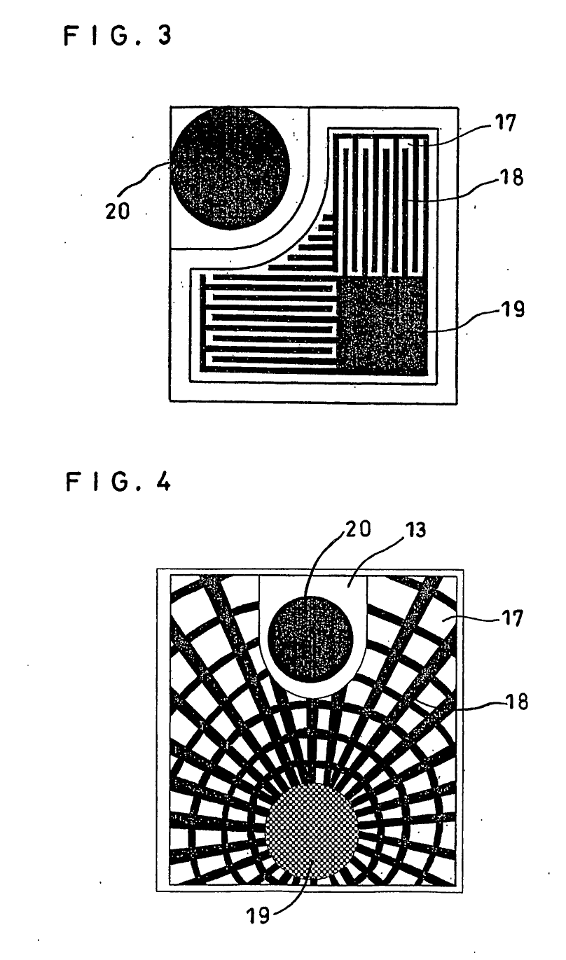

In Example 4, the procedure of Example 1 was repeated, except that an n-type GaN contact layer having a carrier concentration of 6×10¹⁸ cm⁻³ and a thickness of 3 μm, an active layer of a multiple quantum well structure including GaN well layers having a thick portion of 3 nm and a thin portion of 1.5 nm or less, and a p-type GaN contact layer having a carrier concentration of 5×10¹⁷ cm⁻³ were employed to thereby fabricate an electrode formed of Au/NiO on an wafer having the same stacked structure as employed in Example 1. The light-permeable electrode pattern was changed to a comb-like shape as shown in FIG. 3. The fabricated element exhibited a device operation forward voltage of 3.3 V at a current of 20 mA. The emission output was found to be 6 mW.

### EXAMPLE 5

In Example 5, in a manner similar to that of Example 1, a Pt electrode having a thickness of 0.5 nm was fabricated through sputtering on a wafer having the same stacked structure as employed in Example 1. The light-permeable electrode pattern was changed to a cobweb-like shape as shown in FIG. 4. The fabricated element exhibited a device operation forward voltage of 3.1 V at a current of 20 mA. The emission output was found to be 6 mW.

### INDUSTRIAL APPLICABILITY

A light-emitting device of the present invention can operate at low operation voltage, despite having a light-permeable electrode having an aperture for attaining high emission output, and accordingly can favorably be used as an LED, a laser and the like.

1. A gallium nitride compound semiconductor light-emitting device comprising:
a crystalline substrate (10);
a light-emitting layer (15) of a quantum well structure which is formed of a gallium nitride compound semiconductor barrier layer and a gallium nitride compound semiconductor well layer, which light-emitting layer is provided on a second side of the crystalline substrate;
a contact layer (17) formed of a Group III-V compound semiconductor for providing an Ohmic electrode for supplying device operation current to the light-emitting layer; and
an Ohmic electrode (18) which is provided on the contact layer and has an aperture through which a portion of the contact layer is exposed,
wherein the Ohmic electrode exhibits light permeability with respect to light emitted from the light-emitting layer, and the well layer contains a thick portion having a large thickness and a thin portion having a small thickness.

2. A gallium nitride compound semiconductor light-emitting device according to claim 1, wherein the well layer contains a portion having a thickness of 1.5 nm to 0 nm.

3. A gallium nitride compound semiconductor light-emitting device according to claim 1, wherein either the barrier layer or the well layer is doped with an impurity element.

4. A gallium nitride compound semiconductor light-emitting device according to claim 3, wherein only the barrier layer is doped with an impurity element.

5. A gallium nitride compound semiconductor light-emitting device according to claim 4, wherein the predetermined impurity element added only to the barrier layer is silicon.

6. A gallium nitride compound semiconductor light-emitting device according to claim 1, wherein the contact layer (17) is doped with an n-type impurity element and has a carrier concentration of 5×10¹⁸ cm⁻³ to 2×10¹⁹ cm⁻³.

7. A gallium nitride compound semiconductor light-emitting device according to claim 1, wherein the contact layer (17) is doped with a p-type impurity element and has a carrier concentration of 1×10¹⁷ cm⁻³ to 1×10¹⁹ cm⁻³.

8. A gallium nitride compound semiconductor light-emitting device according to claim 7, wherein the contact layer (17) is doped with a p-type impurity element and has a carrier concentration of 1×10¹⁷ cm⁻³ to 5×10¹⁸ cm⁻³.

9. A gallium nitride compound semiconductor light-emitting device according to claim 1, wherein the contact layer (17) has a thickness of 1 μm to 3 μm.

10. A gallium nitride compound semiconductor light-emitting device according to claim 1, wherein the Ohmic electrode (18) exhibits a transmittance at the wavelength of emitted light of 30% or higher.

11. A gallium nitride compound semiconductor light-emitting device according to claim 1, wherein the Ohmic electrode (18) has a thickness of 1 nm to 100 nm.

12. A gallium nitride compound semiconductor light-emitting device according to claim 1, further comprising a metallic reflecting mirror (21) for reflecting light emitted from the light-emitting layer (15) to the outside, which mirror is provided on a first side of the crystalline substrate (10), wherein the metallic reflecting mirror (21) contains a metallic material identical to that contained in the Ohmic electrode (18).

13. A gallium nitride compound semiconductor light-emitting device according to claim 12, wherein the metallic reflecting mirror (18) has a multilayer structure including a metallic film which contains a metallic material identical to that contained in the Ohmic electrode (18).

14. A gallium nitride compound semiconductor light-emitting device according to claim 1, wherein the metallic reflecting mirror (21) contains a single-metal film or an alloy film formed from at least one member selected from the group consisting of silver, platinum, rhodium and aluminum.

15. A gallium nitride compound semiconductor light-emitting device according to claim 1, wherein the metallic reflecting mirror (21) is in the form of multilayer film.

16. A light-emitting diode employing the gallium nitride compound semiconductor light-emitting device according to claim 1.

17. A lamp employing the gallium nitride compound semiconductor light-emitting device according to claim 1.
